(19) United States
(12) Patent Application Publication
(10) Pub. No.: US 2024/0410986 A1
(43) Pub. Date: Dec. 12, 2024

(54) DETECTOR ELEMENT AND METHOD FOR OPERATING A LIDAR MODULE

(71) Applicant: ams-OSRAM International GmbH, Regensburg (DE)

(72) Inventors: Reiner WINDISCH, Pettendorf (DE); Hubert HALBRITTER, Dietfurt (DE); Simon LANKES, Regensburg (DE)

(73) Assignee: ams-OSRAM International GmbH, Regensburg (DE)

(21) Appl. No.: 18/702,037

(22) PCT Filed: Sep. 27, 2022
(86) PCT No.: PCT/EP2022/076822

§ 371 Date: Apr. 17, 2024

(30) Foreign Application Priority Data
Oct. 19, 2021 (DE) 102021127038.3

(51) Int. Cl. G01S 7/481; G01S 7/4912; G01S 17/34; H01L 31/0352; H01L 31/103

(52) U.S. Cl. CPC G01S 7/4816; G01S 7/4814; G01S 7/4917; G01S 17/34; H01L 31/035236; H01L 31/103

(57) ABSTRACT

The invention relates to a detector element which has the following features: an epitaxial semiconductor layer sequence including at least two active layers which are designed to absorb electromagnetic radiation with a wavelength L1, wherein the epitaxial semiconductor layer sequence has a first main surface and a second main surface lying opposite the first main surface, each surface being designed to couple in and couple out electromagnetic radiation, and at least three electric connection contacts which are designed to electrically contact the active layers, an electric connection contact being arranged between two active layers. The invention additionally relates to a lidar module and to a method for operating a lidar module.

### CROSS-REFERENCE TO RELATED APPLICATIONS

The present application is a national stage entry from International Application No. PCT/EP2022/076822, filed on Sep. 27, 2022, published as International Publication No. WO 2023/066620 A1 on Apr. 27, 2023, and claims priority to German Patent Application No. 10 2021 127 038.3, filed Oct. 19, 2021, the disclosures of all of which are hereby incorporated by reference in their entireties.

### FIELD

A detector element, a lidar module and a method for operating a lidar module are specified.

### BACKGROUND

At least one object of certain embodiments is to provide an improved detector element for differential detection of frequency modulated continuous wave lidar (FMCW lidar) signals.

### SUMMARY

According to at least one embodiment, the detector element comprises an epitaxial semiconductor layer sequence with at least two active layers.

The epitaxial semiconductor layer sequence comprises, for example, a III/V compound semiconductor material. A III/V compound semiconductor material comprises at least one element from the third main group, such as B, Al, Ga, In, and one element from the fifth main group, such as N, P, As. In particular, the term “III/V compound semiconductor material” comprises the group of binary, ternary or quaternary compounds which contain at least one element from the third main group and at least one element from the fifth main group, for example nitride and phosphide compound semiconductors. Such a binary, ternary or quaternary compound can also comprise, for example, one or more dopants and additional components.

In particular, the semiconductor layer sequence comprises an arsenide compound semiconductor material, wherein the semiconductor layer sequence or at least a part thereof, particularly preferably at least the active layer, preferably comprises AlₙGaₘIn₁₋ₙ₋ₘAs, where 0≤n≤1, 0≤m≤1 and n+m≤1. This material does not necessarily comprise a mathematically exact composition according to the above formula. Rather, it can comprise one or more dopants as well as additional components. For the sake of simplicity, however, the above formula only contains the essential components of the crystal lattice (Al or As, Ga, In), even if these may be partially replaced by small amounts of other substances.

According to at least one further embodiment of the detector element, the at least two active layers are configured for absorbing electromagnetic radiation with a wavelength L1. Preferably, the wavelength L1 of the electromagnetic radiation to be absorbed is in the infrared spectral range, for example between 800 nanometers and 1800 nanometers inclusive.

According to at least one further embodiment of the detector element, the epitaxial semiconductor layer sequence comprises a first main surface and a second main surface opposite to the first main surface, each of which is configured for coupling in and for coupling out electromagnetic radiation, in particular with the wavelength L1.

Here and in the following, main surfaces of the epitaxial semiconductor layer sequence are arranged normal to the growth direction of the semiconductor layer sequence. In other words, main surfaces of the semiconductor layer sequence are oriented parallel to the main extension plane of semiconductor layers of the semiconductor layer sequence. The main surfaces delimit the semiconductor layer sequence. In particular, epitaxial semiconductor layers are arranged between the two main surfaces.

According to at least one further embodiment of the detector element, the epitaxial semiconductor layer sequence is arranged on a carrier. The carrier can, for example, comprise the growth substrate or be formed from the growth substrate on which the semiconductor layer sequence is epitaxially grown. Alternatively, the carrier is not a growth substrate. For example, the carrier comprises gallium arsenide, silicon, or sapphire or consists of gallium arsenide, silicon, or sapphire. In particular, the carrier is transparent to electromagnetic radiation of wavelength L1 that is at least partially absorbed by the at least two active layers of the semiconductor layer sequence. Here and in the following transparent means that at least 80%, preferably at least 90%, of the electromagnetic radiation with the wavelength L1 that is incident on the carrier is transmitted through the carrier.

According to at least one further embodiment, the detector element comprises at least three electrical terminal contacts that are configured for electrically contacting the active layers, wherein one electrical terminal contact is arranged between two active layers.

For example, the epitaxial semiconductor layer sequence comprises exactly two active layers and exactly three electrical terminal contacts, wherein one electrical terminal contact is arranged on each of the two main surfaces of the epitaxial semiconductor layer sequence, while a third electrical terminal contact is arranged between the two active layers. Consequently, the two active layers can be electrically contacted independently of each other.

According to an embodiment, the detector element comprises:
an epitaxial semiconductor layer sequence with at least two active layers that are configured for absorbing electromagnetic radiation having a wavelength L1, wherein the epitaxial semiconductor layer sequence comprises a first main surface and a second main surface opposite to the first main surface, each of which is configured for coupling in and for coupling out electromagnetic radiation, and
at least three electrical terminal contacts that are configured for electrically contacting the active layers, wherein one electrical terminal contact (8) is arranged between two active layers (3, 4).

A detector element as described herein is particularly suitable for differential detection of FMCW lidar signals. A transmission signal, which in particular comprises frequency-modulated laser light with a wavelength L1 in the infrared spectral range, and a receiving signal are counter-propagating and superimposed in the detector element. The receiving signal comprises the transmission signal that is at least partially reflected by an external object. Here and in the following, counter-propagating means that the transmission signal is coupled into the detector element via the first main surface, while the receiving signal is coupled into the detector element via the second main surface, or vice versa.

By superimposing the counter-propagating transmission signal and the receiving signal, a standing electromagnetic wave with a wavelength L1/n is formed in the detector element, for example, where n denotes an average refractive index of the semiconductor material of the semiconductor layer sequence in the detector element. For example, the superposition of two counter-propagating, linearly polarized, plane electromagnetic waves of the transmission signal and the receiving signal with electric field strengths of the form E_{1,2}=E_{1,2}e^{i(k}^{_{1,2}}^{x-ω}^{_{1,2}}^{t)}, where E_{1,2} are amplitudes, ω_{1,2} are frequencies, x is a propagation direction and t is a time, and where the wavenumbers k_{1,2} of the counter-propagating waves satisfy

$${k}_{1} = - {k}_{2} = k = \frac{2 π n}{L 1} ,$$

leads to an intensity of an electric field in the detector element given by:

$${\vert {E}_{1} + {E}_{2} \vert}^{2} = {E}_{1}^{2} + {E}_{2}^{2} + 2 {E}_{1} {E}_{2} cos ( 2 kx - ( {ω}_{1} - {ω}_{2} ) t ) .$$

In particular, a phase of the standing wave is proportional to a frequency difference ω₁-ω₂.

When measuring distances using FMCW lidar, the frequency ω₁ of the transmission signal is increased or decreased linearly as a function of time. The superposition of the transmission signal and the receiving signal in the detector element leads to a beating, whereby the difference frequency ω₁-ω₂ between the frequency ω₁ of the transmission signal and the frequency ω₂ of the receiving signal is proportional to the distance to the external object.

The detector element is configured for measuring the difference frequency ω₁-ω₂ between the transmission signal and the receiving signal. In particular, the detection is differential, whereby a disturbing, time-independent part E₁²+E₂² of the standing electromagnetic wave is eliminated. Differential detection is carried out by determining the intensity of the electric field in the detector element at two different locations, which are arranged at a distance of a quarter of the wavelength, i.e. L1/(4*n), for example. In particular, photocurrents generated by the active layers are proportional to the intensity of the electric field. By subtracting the photocurrents of the two active layers at a distance of L1/(4*n), whereby the distance can also be larger by multiples of one half of the wavelength L1/(2*n), the time-independent component of the standing electromagnetic wave is eliminated, while the component oscillating in time with the difference frequency is added. A measurement signal, which is obtained by subtracting the two photocurrents of the two active layers thus exhibits a temporal oscillation with the difference frequency ω₁-ω₂.

Lidar detectors with a co-propagating superposition of the transmission signal and the receiving signal require, in particular, an optical circulator or separate optics for a transmitter and a receiver. With the detector element described herein, a single optical system can be used for the transmitter and the receiver, whereby no optical circulator is required. This simplifies the design of the lidar detector. Furthermore, differential detection of the difference frequency improves the signal-to-noise ratio. In particular, disturbing intensity fluctuations that can occur during frequency modulation of the transmission signal are eliminated. In particular, with the detector element described herein, differential detection with a single semiconductor component is possible. Accordingly, it is not necessary to arrange and adjust two photodetectors.

According to a further embodiment of the detector element, each active layer comprises at least one p-doped semiconductor layer and at least one n-doped semiconductor layer forming a photodiode. In particular, the photodiode is configured for converting electromagnetic radiation into an electrical photocurrent.

According to at least one further embodiment of the detector element, at least one active layer comprises a multiple quantum well structure.

Here and in the following, the term quantum well structure includes in particular any structure in which charge carriers can experience a quantization of their energy states due to confinement. In particular, the term quantum well structure does not include any indication of the dimensionality of the quantization. It therefore includes quantum wells, quantum wires and quantum dots and any combination of these structures.

According to a further embodiment of the detector element, the active layers have thicknesses that are less than a quarter of the wavelength L1/n in the semiconductor layer sequence, where n is an average refractive index of the semiconductor layer sequence.

In particular, the detector element is configured for the differential detection of a beating frequency, which arises by superimposing a transmission signal with a counter-propagating receiving signal in the detector element. Due to absorption of the electromagnetic radiation in the active layer, the electric field of the standing electromagnetic wave is averaged over the thickness of the active layer. A thickness of the active layer that is larger than a quarter of the wavelength L1/n in the semiconductor layer sequence therefore does not lead to any increased sensitivity of the detector element with regard to the spatially oscillating component of the standing electromagnetic wave.

According to at least one further embodiment of the detector element, an average distance A1 between two active layers, between which an electrical terminal contact is arranged, is A1=L1*(2*m−1)/(4*n), where n is an average refractive index of the semiconductor layer sequence and m is a positive integer.

The average distance A1 is preferably measured from the center of an active layer to the center of an adjacent active layer. The average distance A1 can deviate from the distance A1 specified above within a tolerance of at most ±0.25*L1/(4*n).

In particular, the detector element is configured for the differential detection of a beating frequency of the spatially oscillating component of the standing electromagnetic wave. In order to maximize a signal-to-noise ratio, it is thus advantageous if an average distance between two active layers is, for example, one quarter, three quarters or five quarters of the wavelength L1/n in the semiconductor layer sequence. In other words, at one point in time, the first active layer is located at a node of the standing electromagnetic wave, for example, while the second active layer is located at an intensity maximum of the standing electromagnetic wave, for example.

According to at least one further embodiment of the detector element, two active layers, between which an electrical terminal contact is arranged, are formed as photodiodes with opposite forward directions.

The two photodiodes of the detector element with the opposite forward direction are, for example, part of a differential amplifier circuit that only measures the spatially oscillating component of the standing electromagnetic wave within the detector element. In particular, this allows to eliminate the disturbing constant component of the standing electromagnetic wave. This reduces, for example, the intensity of noise when the transmission signal is superimposed on the receiving signal, which means that an improved signal-to-noise ratio can be achieved.

According to at least one further embodiment of the detector element, the two active layers, between which an electrical terminal contact is arranged, are formed as photodiodes with the same forward direction, wherein a tunnel diode is arranged between the active layers.

The two photodiodes of the detector element with the same forward direction are, for example, part of an electrical circuit of a symmetrical photodetector. This allows small differences in the photocurrents of the two photodiodes to be measured accurately using a transimpedance amplifier. In particular, an output signal of a symmetrical photodetector is proportional to the difference in the photocurrents of the two photodiodes.

According to at least one further embodiment of the detector element, thicknesses of the active layers increase or decrease in the growth direction of the epitaxial semiconductor layer sequence.

Electromagnetic waves, for example of a transmission signal, are at least partially absorbed as they pass through the detector element. As a result, the intensity of the electromagnetic radiation in the detector element decreases in the propagation direction of the electromagnetic wave. This gives rise to a systematically different detector signal in the at least two photodiodes of the detector element. In order to compensate for such systematic differences in the detector signals, thicknesses of the active layers can increase in the propagation direction of the electromagnetic radiation. In particular, the transmission signal dominates the overall intensity of the electromagnetic radiation in the detector element. For this reason, it may be advantageous for the thicknesses of the active layers to increase in the propagation direction of the transmission signal.

According to at least one further embodiment of the detector element, the epitaxial semiconductor layer sequence has a thickness such that an optical path length of electromagnetic radiation with a wavelength L1 between the first main surface and the second main surface of the epitaxial semiconductor layer sequence corresponds to an integer multiple of the wavelength L1.

By selecting the thickness of the epitaxial semiconductor layer sequence as described above, an electromagnetic wave of wavelength L1 comprises the same phase after passing through the detector element as an electromagnetic wave of the same wavelength that does not pass through the detector element. If, for example, several detector elements are arranged next to each other in a direction perpendicular to the propagation direction of the transmission signal, a corresponding choice of the thicknesses of the epitaxial semiconductor layer sequences ensures that a wavefront of the transmission signal is distorted less strongly or not at all when passing through the detector elements arranged next to each other.

According to at least one further embodiment, the detector element comprises a semiconductor layer sequence with at least three active layers, wherein an average distance A2 between two neighboring active layers, between which no electrical terminal contact is arranged, is A2=L1*m/(2*n), wherein n is an average refractive index of the semiconductor layer sequence m is a positive integer.

In order to increase the signal-to-noise ratio, it can be advantageous to arrange several active layers of the epitaxial semiconductor layer sequence in series, which together form a photodiode of the detector element. An average distance between two neighboring active layers forming a photodiode is preferably an integer multiple of half the wavelength L1/n in the semiconductor layer sequence, where n is the average refractive index of the semiconductor layer sequence. Due to this choice of distance, the intensity of the standing wave in the detector element has the same phase at the locations of the two active layers. Thus, the photocurrents of the two active layers add up, thereby increasing the signal-to-noise ratio.

A lidar module is further specified herein. All features disclosed for the detector element are also disclosed for the lidar module, and vice versa.

According to at least one embodiment, the lidar module comprises at least one detector element. In particular, the detector element corresponds to at least one of the embodiments described herein and is configured for a differential detection of a beating frequency between a transmission signal and a counter-propagating receiving signal.

According to at least one further embodiment, the lidar module comprises a laser light source configured for generating coherent electromagnetic radiation at the wavelength L1.

Laser light is generated by stimulated emission and, in contrast to electromagnetic radiation, which is generated by spontaneous emission, generally comprises a very high coherence length, a very narrow spectral linewidth and/or a high degree of polarization. Preferably, the coherence length of the laser light source is greater than twice the maximum distance between the lidar module and an external object that should still be detectable. For example, the laser light source comprises a surface-emitting laser diode, an edge-emitting laser diode, a fiber laser, a fiber-amplified laser, a distributed feedback laser (DFB laser), or any variants thereof.

According to at least one further embodiment of the lidar module, the electromagnetic radiation generated during operation by the laser light source is coupled into the detector element via the first main surface and is coupled out via the second main surface.

In particular, a transmission signal generated by the laser light source passes through the detector element at least partially before it is emitted from the lidar module and subsequently reflected back at least partially by an external object.

According to at least one further embodiment of the lidar module, the laser light source comprises a surface-emitting semiconductor layer sequence, wherein the surface-emitting semiconductor layer sequence and the epitaxial semiconductor layer sequence of the detector element form a monolithic semiconductor layer stack.

In particular, the surface-emitting semiconductor layer sequence of the laser light source and the epitaxial semiconductor layer sequence of the detector element can be parts of a common epitaxial semiconductor layer sequence, which are epitaxially grown on top of each other as part of an epitaxial growth process. The monolithic semiconductor layer stack comprises, for example, two dielectric mirrors between which an active layer for generating coherent electromagnetic radiation is arranged. The epitaxial semiconductor layer sequence of the detector element is arranged on one of these dielectric mirrors. The dielectric mirrors comprise, for example, a sequence of dielectric layers forming a Bragg mirror.

According to at least one embodiment, the lidar module has a plurality of detector elements arranged on a transparent carrier, which form a two-dimensional detector array.

By arranging a plurality of detector elements in a two-dimensional detector array, in particular a direction of the receiving signal can be determined in conjunction with an imaging optics. Thus, a lidar module described herein with a two-dimensional detector array is suitable for determining a distance and a direction of an external object at the same time. Furthermore, a radial velocity of the external object can be determined via a Doppler shift of the difference frequency between the transmission signal and the receiving signal. Alternatively, the plurality of detector elements can also be arranged as a one-dimensional detector array or form a one-dimensional detector array.

Furthermore, a method for operating a lidar module is specified herein. All features of the lidar module are also disclosed for the method for operating a lidar module and vice versa.

According to at least one embodiment, the method for operating a lidar module comprises transmitting a transmission signal, wherein the transmission signal comprises a frequency modulated electromagnetic wave generated by the laser light source which passes through the detector element and is subsequently at least partially reflected by an external object.

In particular, the lidar module corresponds to at least one of the embodiments described herein. The transmission signal generated by the laser light source is thus preferably coupled into the detector element of the lidar module via the first main surface and coupled out via the second main surface of the detector element. It is also possible that only a part of the transmission signal passes through the detector element.

According to at least one further embodiment of the method for operating a lidar module, a receiving signal is received which comprises the transmission signal that is at least partially reflected by an external object. The receiving signal is coupled into the detector element via the second main surface and is superimposed there with the counter-propagating transmission signal, whereby a standing electromagnetic wave is formed.

According to a further embodiment of the method for operating a lidar module, a differential measurement of a beating frequency of the standing wave is performed by measuring the photocurrents of the active layers with a differential amplifier.

A differential amplifier is particularly suitable for differential measurement of the photocurrents of a detector element in which the active layers form two photodiodes with opposite forward directions. With a differential amplifier, the amplification of the photocurrents of the two photodiodes can be adjusted separately. In particular, this allows to compensate a systematic difference in intensity of the electromagnetic field in the two photodiodes.

Alternatively, a transimpedance amplifier can be used for symmetrical photodetection with a detector element in which the active layers form two photodiodes with the same forward direction.

According to at least one further embodiment of the method for operating a lidar module, a distance to the external object is determined from the measured beating frequency.

In continuous wave lidar systems, a frequency of the transmission signal is periodically increased and/or decreased linearly as a function of time, for example. The difference frequency between the transmission signal and the receiving signal at the time of detection of the receiving signal is thus proportional to a time-of-flight of the transmission signal between the transmission and the reception of the transmission signal that is at least partially reflected by an external object. The distance to the external object can be determined from the time-of-flight. For example, the difference frequency can be determined using a fast Fourier transformation of the output signal of the differential amplifier. Furthermore, a Doppler shift of the frequency of the receiving signal can be used to determine a radial velocity of the external object.

According to at least one further embodiment of the method for operating a lidar module, a systematic difference in intensity of the electromagnetic radiation in the active layers is compensated by a dynamic circuit.

Both the transmission signal and the receiving signal are at least partially absorbed as they pass through the detector element. The overall intensity of the electromagnetic field within the detector element is dominated in particular by the stronger transmission signal. Thus, the overall intensity of the electromagnetic field in the detector element decreases in the direction in which the transmission signal propagates through. If the active layers in the detector element have the same thickness, this results in a systematic difference in the photocurrents generated by the active layers. In particular, this systematic difference can be compensated by a dynamic circuit. For example, the amplification of the individual photocurrents can be adjusted separately in a differential amplifier circuit.

Further advantageous embodiments and further developments of the detector element, the lidar module and the method for operating the lidar module are apparent from the exemplary embodiments described in conjunction with the figures below.

### BRIEF DESCRIPTION OF THE DRAWINGS

FIG. 1 shows a schematic sectional view of a detector element according to an exemplary embodiment.

FIG. 2 shows a schematic equivalent circuit diagram of a detector element according to an exemplary embodiment.

FIG. 3 shows a schematic electrical circuit of a differential amplifier with a detector element according to an exemplary embodiment.

FIGS. 4, 5 and 6 show schematic band structures of detector elements, as well as schematic geometric arrangements of the active layers in the detector elements according to various exemplary embodiments.

FIG. 7 shows an equivalent circuit diagram of a detector element according to a further exemplary embodiment.

FIG. 8 shows a schematic electrical circuit for symmetrical photodetection with a detector element according to a further exemplary embodiment.

FIG. 9 shows a schematic geometric arrangement of active layers in a schematic sectional view of a detector element.

FIG. 10 shows a schematic sectional view of a detector element according to a further exemplary embodiment.

FIGS. 11 and 12 show lidar modules according to different embodiments.

FIGS. 13 and 14 show detector arrays according to different embodiments.

FIGS. 15, 16, 17, 18 and 19 show lidar modules according to different embodiments.

### DETAILED DESCRIPTION

Elements that are identical, similar or have the same effect are denoted with the same reference signs in the figures. The figures and the proportions of the elements shown in the figures are not to be regarded as true to scale. Rather, individual elements, in particular layer thicknesses, may be shown exaggeratedly large for better visualization and/or understanding.

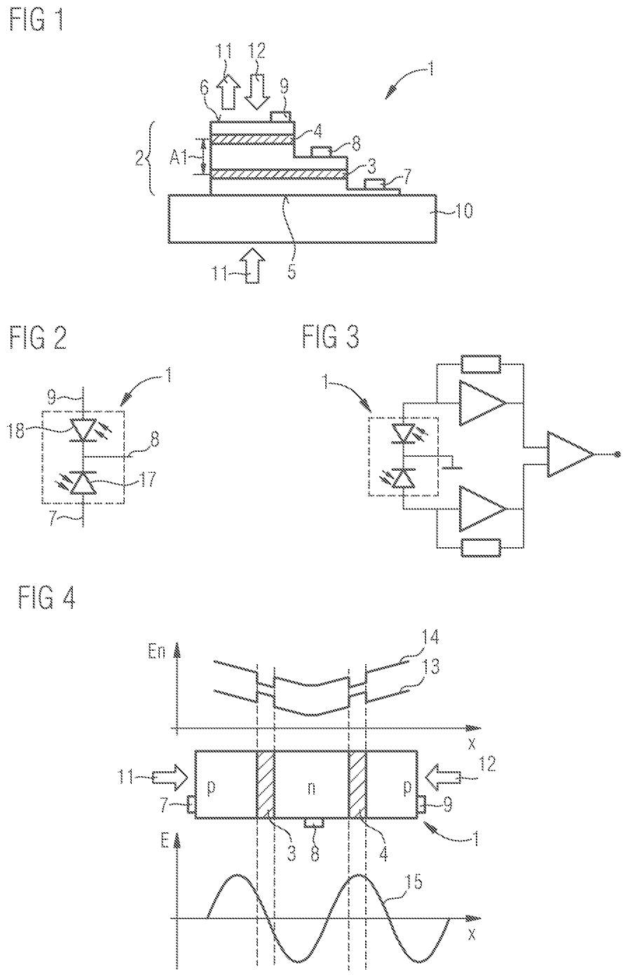

FIG. 1 shows a schematic sectional view of a detector element 1 comprising an epitaxial semiconductor layer sequence 2 on a carrier 10. In particular, the carrier 10 is a growth substrate consisting, for example, of InP or GaAs, on which the epitaxial semiconductor layer sequence 2 is epitaxially grown. The semiconductor layer sequence 2 comprises two active layers 3, 4, which have an average distance A1 and are configured to absorb electromagnetic radiation of a wavelength L1. The average distance A1 is L1/(4*n), where n is the average refractive index of the semiconductor layer sequence 2 for electromagnetic radiation of wavelength L1. In other words, the average distance A1 is a quarter of the wavelength of the electromagnetic radiation to be absorbed in the medium of the detector element 1. Alternatively, the distance A1 can also be greater by integer multiples of half the wavelength in the medium L1/(2*n), for example 3/4, 5/4, 7/4 of the wavelength of the electromagnetic radiation to be absorbed in the medium of the detector element 1.

The semiconductor layer sequence 2 is structured in such a manner that a region between the two active layers 3, 4 is also electrically contacted. In particular, the detector element comprises three electrical terminal contacts 7, 8, 9, with one terminal contact 8 being arranged between the two active layers 3, 4.

Electromagnetic radiation of the transmission signal 11 is coupled in via the first main surface 5 of the epitaxial semiconductor layer sequence 2 and, after passing through the epitaxial semiconductor layer sequence 2, is coupled out via the second main surface 6. The receiving signal 12, which comprises the transmission signal 11 that is at least partially reflected by an external object, is coupled into the detector element 1 via the second main surface 6 of the epitaxial semiconductor layer sequence 2.

Due to the superposition of the transmission signal 11 and the counter-propagating receiving signal 12 in the detector element 1, a standing electromagnetic wave 15 is formed, the beating frequency of which corresponds to the difference frequency between the transmission signal 11 and the receiving signal 12. By selecting the distance A1 as described above, at a given point in time the first active layer 3 is located at a node, i.e. at a point of vanishing intensity of the standing electromagnetic wave 15, for example, while the second active layer 4 is located at an antinode, i.e. at a point of maximum intensity of the standing electromagnetic wave 15. A differential measurement, in which the photocurrents of the two active layers 3, 4 are subtracted, can thus eliminate a disturbing, time-independent component of the standing electromagnetic wave 15.

Average thicknesses D of the active layers 3, 4 are smaller than L1/(4*n), i.e. smaller than a quarter of the wavelength of the electromagnetic radiation to be absorbed in the medium of the detector element 1. Here, thicknesses D of the active layers 3, 4 are specified in the growth direction of the semiconductor layer sequence 2, i.e. perpendicular to a main extension plane of the active layers 3, 4. Although active layers 3, 4 with larger thicknesses D would absorb more electromagnetic radiation, this does not improve the signal-to-noise ratio, because the active layers 3, 4 average the electromagnetic field of the standing electromagnetic wave 15 in the detector element 1 over the thicknesses D of the active layers 3, 4. In particular, a thickness D of the active layers 3, 4 is not an integer multiple of the wavelength L1/n in the medium, as in this case the beating at the difference frequency between the transmission signal 11 and the receiving signal 12 would be averaged out and would therefore not be measurable.

FIG. 2 shows a schematic equivalent circuit diagram of the detector element 1 of FIG. 1, wherein the two active layers 3, 4 of the detector element 1 form two photodiodes 17, 18, which are arranged with opposite forward direction. A photodiode 17, 18 in the equivalent circuit diagram can also comprise several active layers 3 and 3′, or 4 and 4′, between which no electrical terminal contact is arranged.

FIG. 3 shows a schematic differential amplifier circuit, whereby the detector element 1 is represented by the equivalent circuit diagram of FIG. 2. In particular, the differential amplifier is configured to subtract the photocurrents of the two photodiodes, thereby eliminating the disturbing DC component of the standing electromagnetic wave 15. The output of the differential amplifier thus provides an electrical voltage that oscillates in time with the beating frequency, i.e. with the difference frequency between the transmission signal 11 and the receiving signal 12. The amplification of the photocurrents of the two photodiodes can be adjusted separately, whereby a systematic difference in intensity of the electromagnetic field at the two photodiodes can be compensated.

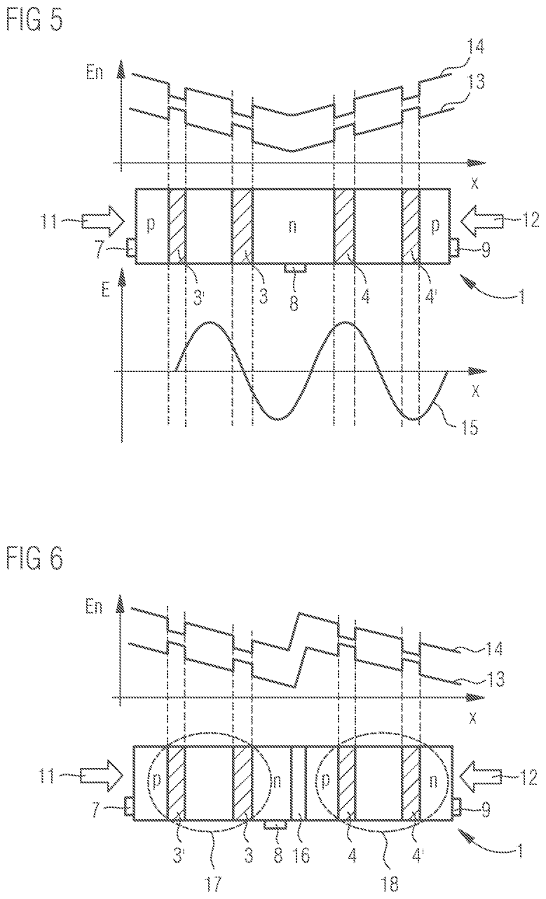

FIG. 4 shows a schematic view of the band structure of a detector element 1 as a function of the propagation direction x of the transmission signal 11. In particular, an energy En of the valence band 13 and the conduction band 14 is shown in conjunction with the geometric arrangement of the active layers 3, 4 in the detector element 1. Furthermore, FIG. 4 shows a snapshot of the electric field E of the standing electromagnetic wave 15 in the detector element 1. The average distance A1 between the active layers 3, 4 is 3*L1/(4*n), i.e. three quarters of the wavelength of the electromagnetic radiation to be absorbed in the medium of the detector element 1. The phase of the standing electromagnetic wave 15 increases or decreases linearly as a function of time, wherein the slope of the linear function is proportional to the difference frequency between the transmission signal 11 and the receiving signal 12. The photocurrent generated by the active layers 3, 4 thus comprises a component that oscillates in time with the difference frequency.

In the exemplary embodiment of the detector element 1 shown here, an n-doped semiconductor region is arranged between two p-doped semiconductor regions. Alternatively, a p-doped semiconductor region can also be arranged between two n-doped semiconductor regions. Thus, the two photodiodes formed by the two active layers 3, 4 are arranged with opposite forward directions.

FIG. 5 shows a further exemplary embodiment of a detector element 1 with a schematic representation of the energy gap between the valence band 13 and the conduction band 14 as a function of the propagation direction x of the transmission signal 11. In addition, a snapshot of the standing electromagnetic wave 15 in the detector element 1 is shown.

In contrast to the exemplary embodiment in FIG. 4, the detector element 1 in FIG. 5 comprises two active layers 3, 3′ and 4, 4′ between two terminal contacts 7, 8 and 8 and 9, respectively. An average distance A2 between two active layers 3, 3′ or 4, 4′, between which no terminal contact is arranged, is an integer multiple of L1/(2*n), i.e. half the wavelength of the electromagnetic radiation to be absorbed in the detector element 1. Thus, the intensity of the standing electromagnetic wave 15 has the same phase at the positions of the two active layers 3, 3′ or 4, 4′ between which no electrical terminal contact is arranged. As a result, an effective absorption region can be increased and a signal-to-noise ratio of the detector element 1 can be improved. Active layers 3, 3′ or 4, 4′, between which no electrical terminal contact is arranged, act as a common photodiode of the detector element 1. In particular, the thicknesses D of the active layers are less than L1/(4*n), i.e. less than a quarter of the wavelength of the standing electromagnetic wave in the detector element 1. Alternatively, also more than two active layers can be arranged at a distance A2, forming a photodiode of the detector element 1.

FIG. 6 shows a further exemplary embodiment of a detector element 1 with a schematic representation of the energy gap between the valence band 13 and the conduction band 14 as a function of the propagation direction x of the transmission signal 11. In contrast to the exemplary embodiment in FIG. 5, the two photodiodes 17, 18, which are formed by the active layers 3 and 3′ and 4 and 4′ respectively, have the same forward direction. For this reason, a tunnel diode 16 is arranged between the two pairs of active layers 3, 3′ and 4, 4′. The detector element 1 shown in FIG. 5 is particularly suitable for symmetrical photodetection with a transimpedance amplifier.

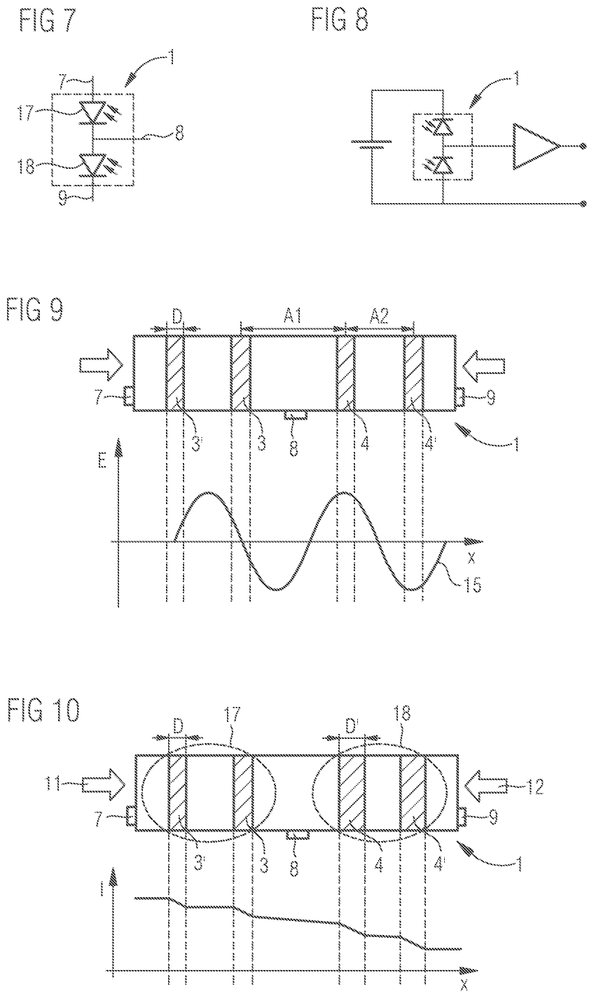

FIG. 7 shows an equivalent circuit diagram of the detector element 1 of FIG. 6, where the two photodiodes 17, 18 have the same forward direction.

FIG. 8 shows a schematic electrical circuit for symmetrical photodetection with a detector element as shown in FIG. 6. The difference between the photocurrents of the two photodiodes is converted into a measurable output voltage by a transimpedance amplifier.

FIG. 9 shows a schematic sectional view of a detector element 1, wherein the geometric arrangement of the active layers 3, 3′, 4, 4′ is shown. The active layers 3, 4, between which an electrical terminal contact 8 is arranged, have a distance A1 of L1*(2*m−1)/(4*n), where m is a positive integer and n is the average refractive index of the semiconductor layer sequence 2. In other words, the distance A1 is an odd integer multiple of a quarter of the wavelength of the electromagnetic radiation to be absorbed in the medium of the detector element 1. The distance A2 between active layers 3, 3′ or 4, 4′, between which no electrical terminal contact is arranged, is m*L1/(2*n), i.e. an integer multiple of half the wavelength of the electromagnetic radiation to be absorbed in the medium of the detector element 1. The thicknesses D of the active layers 3, 3′, 4, 4′ are smaller than L1/(4*n).

For a detector element 1 comprising indium gallium arsenide, the average refractive index n is approximately in the range between 3.4 and 3.5, inclusive. At a wavelength L1 of 1550 nanometers, the wavelength in the detector element is thus approximately 455 nanometers. The thickness D of an active layer 3, 3′, 4, 4′ is therefore less than about 114 nanometers, while the distance A1 between two active layers 3, 4 between which a terminal contact 8 is arranged, is (2*m−1)*114 nanometers, with m a positive integer. The distance A2 between two active layers 3, 3′ or 4, 4′, between which no terminal contact is arranged, is an integer multiple of approximately 228 nanometers.

Correspondingly, at a wavelength L1 of 900 nanometers, D<=64 nanometers, A1=(2*m−1)*64 nanometers and A2=m*128 nanometers.

FIG. 10 shows a schematic sectional view of a detector element 1 in accordance with a further exemplary embodiment, wherein the thicknesses D, D′ of the active layers 3, 3′, 4, 4′ increase in the propagation direction x of the transmission signal 11. The intensity I of the electromagnetic radiation, in particular of the transmission signal 11, decreases due to absorption in the active layers 3, 3′, 4, 4′. This gives rise to a systematic difference in intensity at the two photodiodes 17, 18. This systematic difference in intensity can be balanced or compensated for by a larger thickness of the active layers 4, 4′ of the photodiode 18, which is downstream in propagation direction x. Alternatively, the photodiode 18 arranged downstream in propagation direction x may comprise more active layers than the photodiode 17 arranged upstream.

FIG. 11 shows a schematic sectional view of a lidar module, wherein the detector element 1 and the laser light source 19 form a monolithic semiconductor layer stack 20. The laser light source 19 is a surface-emitting laser diode and comprises an active layer 22 for generating electromagnetic radiation of wavelength L1, for example of 1550 nanometers or 900 nanometers. This active layer 22 is arranged between two dielectric mirrors 21, which form an optical resonator. The dielectric mirrors 21 comprise a plurality of dielectric layers with alternating refractive indices, which form a Bragg reflector. Here, a dielectric mirror 21 on which the detector element 1 is arranged is at least partially transparent for electromagnetic radiation generated during operation. The transmission signal 11 generated by the active layer 22 is coupled into the detector element via the first main surface 5 and coupled out from the lidar module via the second main surface 6. The receiving signal 12 is coupled into the detector element 1 via the second main surface 6.

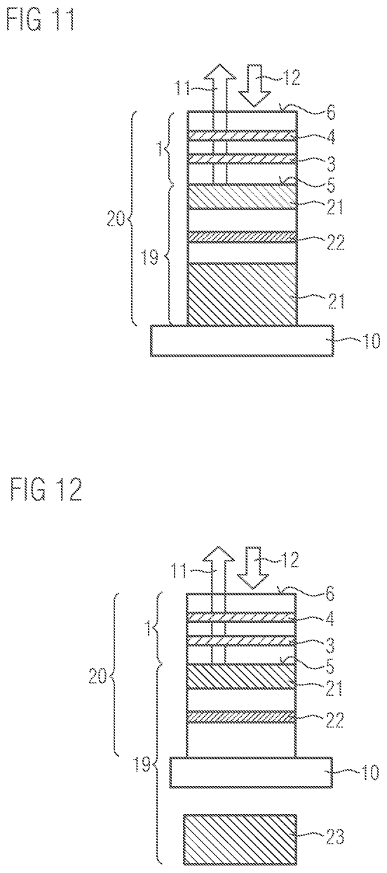

In contrast to the exemplary embodiment in FIG. 11, the exemplary embodiment in FIG. 12 comprises a laser light source 19 with an external mirror 23 that is not integrated into the monolithic semiconductor layer stack 20. The external mirror 23 can be used, for example, to reduce the spectral linewidth of the laser light source 19 and/or to increase the coherence length of the laser light source 19.

A plurality of monolithic lidar modules according to the exemplary embodiments of FIGS. 11 and/or 12 may also be arranged as a one-dimensional array or as a two-dimensional array.

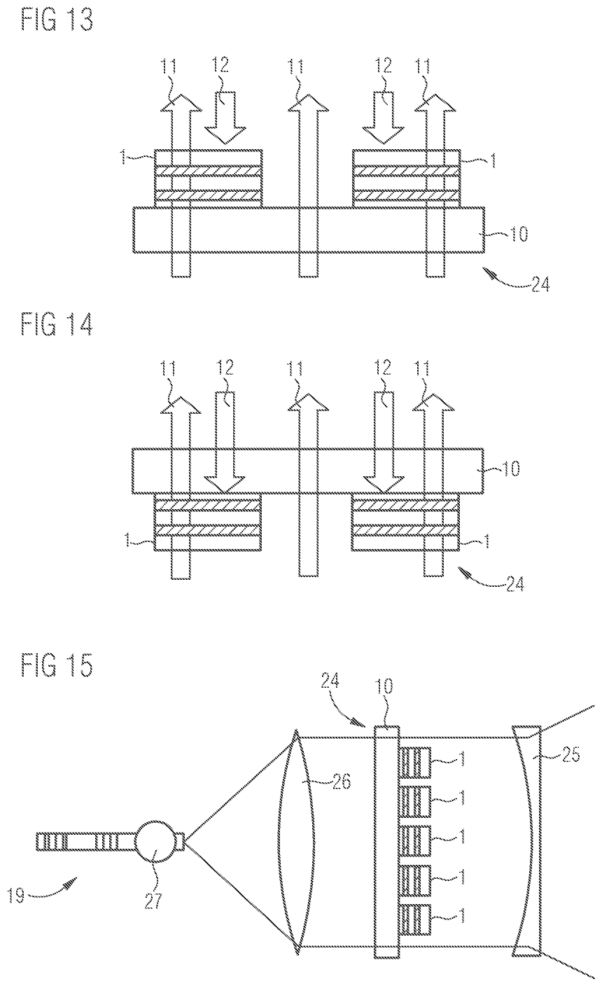

FIGS. 13 and 14 show schematic sectional views of detector arrays 24, wherein a plurality of detector elements 1 are arranged on a common carrier 10. The carrier is transparent to electromagnetic radiation of wavelength L1, which is absorbed by the active layers 3, 4 of the detector elements 1. This means that at least 80% of the electromagnetic radiation with a wavelength L1 incident on the carrier is transmitted through the carrier 10. At least part of the transmission signal 11 is coupled into the detector elements 1. In order to avoid a distortion of wave fronts of the transmission signal, a thickness of the detector elements 1 is selected such that an optical path length of electromagnetic radiation with a wavelength L1 between the first main surface 5 and the second main surface 6 of the epitaxial semiconductor layer sequence 2 corresponds to an integer multiple of the wavelength L1. Thus, the transmission signal 11 after passing through a detector element 1 has the same phase as the part of the transmission signal that passes between the detector elements 1 through the detector array 24. The exemplary embodiments of FIGS. 13 and 14 differ only in the arrangement of the carrier 10 with respect to the propagation direction of the transmission signal 11.

In particular, the detector array 24 can be operated with an external laser light source 19, for example a surface-emitting laser diode, an edge-emitting laser diode, a fiber laser, a fiber-amplified laser, a distributed feedback laser (DFB laser), or any variants thereof, as a lidar module. Preferably, the laser light source 19 is a large-area surface-emitting laser with a reflector comprising a photonic crystal (PCSEL).

FIG. 15 shows an exemplary embodiment of a lidar module comprising a laser light source 19 and a detector array 24. Here, the laser light source 19 is formed as a fiber laser or as laser with a fiber amplifier. The detector array 24 can be designed as a one-dimensional or two-dimensional array. An optical isolator 27 prevents the receiving signal 12 from being coupled into the laser light source 19. A lens 26 or a corresponding optical arrangement collimates the transmission signal 11 such that a parallel bundle of beams is coupled into the detector array 24. A projection optic 25 is configured for coupling out the transmission signal 11 and to couple in the receiving signal 12. This lidar module can be used to determine a direction of the receiving signal 12, for example.

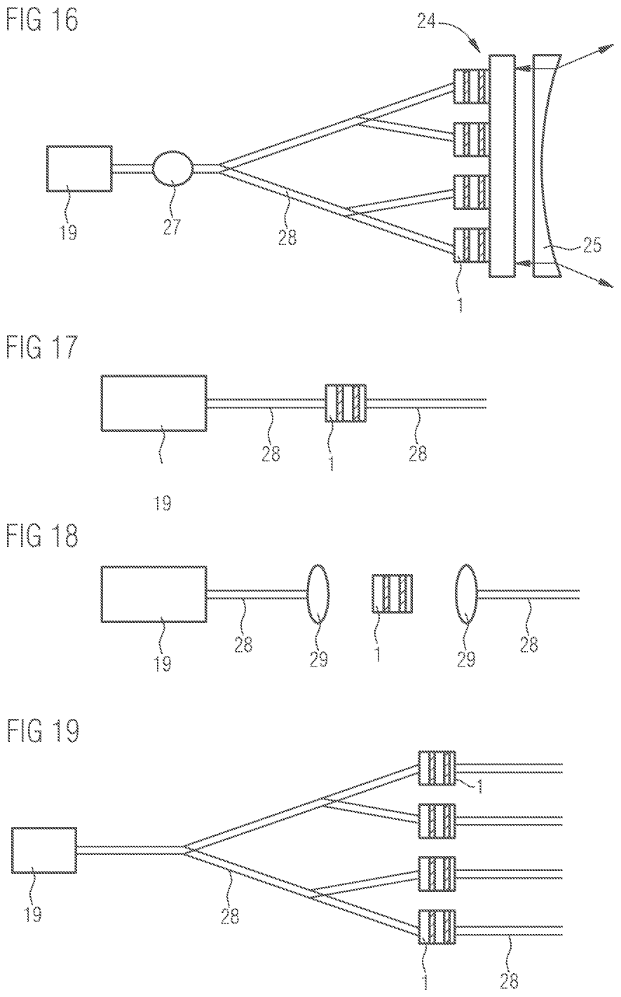

FIG. 16 shows a schematic view of a further lidar module. In contrast to FIG. 15, here the transmission signal 11 is coupled into the detector array 24 via optical waveguides 28, for example via glass fibers. The detector elements 1 are applied to a front face of the fiber ends of the waveguides 28, whereby a diameter of the detector elements 1 is not significantly larger than a fiber diameter of a waveguide 28. As a result, a substantially flat wavefront of the transmission signal 11 can be achieved over the entire surface of the detector array 24. Particularly advantageously, a one-dimensional detector array 24 can be produced on a one-dimensional waveguide array 28 in the form of a photonic integrated circuit (PIC). Alternatively, a two-dimensional fiber bundle can also be combined with a two-dimensional detector array 24.

FIGS. 17, 18 and 19 show lidar modules with laser light sources 19, with detector elements 1 arranged within or between waveguides 28. In FIG. 17, a detector element 1 is integrated between two optical waveguides 28. By contrast, the lidar module in FIG. 18 comprises additional collimating optics 29, with the detector element 1 arranged in a beam waist. FIG. 19 shows a one-dimensional or two-dimensional array of detector elements 1 arranged between two fiber bundles of waveguides 28.

The invention is not limited to the exemplary embodiments by the description thereof. Rather, the invention includes any new feature as well as any combination of features, which includes in particular any combination of features in the patent claims, even if this feature or combination itself is not explicitly stated in the patent claims or exemplary embodiments.

1. A detector element, comprising:
an epitaxial semiconductor layer sequence with at least two active layers that are configured for absorbing electromagnetic radiation having a wavelength L1, wherein the epitaxial semiconductor layer sequence comprises a first main surface and a second main surface opposite to the first main surface, each of which is configured for coupling in and for coupling out electromagnetic radiation, and
at least three electrical terminal contacts that are configured for electrically contacting the active layers, wherein one electrical terminal contact is arranged between two active layers, wherein
during operation of the detector element, a transmission signal is coupled in via the first main surface and is coupled out via the second main surface, and a receiving signal is coupled in via the second main surface.

2. The detector element according to claim 1, wherein each active layer comprises at least one p-doped semiconductor layer and at least one n-doped semiconductor layer forming a photodiode.

3. The detector element according to claim 1, wherein at least one active layer comprises a multiple quantum well structure.

4. The detector element according to claim 1, wherein the active layers have thicknesses that are less than a quarter of the wavelength L1/n in the semiconductor layer sequence, where n is an average refractive index of the semiconductor layer sequence.

5. The detector element according to claim 1, wherein an average distance A1 between two active layers, between which an electrical terminal contact is arranged, is A1=L1*(2*m−1)/(4*n), where n is an average refractive index of the semiconductor layer sequence and m is a positive integer.

6. The detector element according to claim 1, wherein two active layers, between which an electrical terminal contact is arranged, are formed as photodiodes with opposite forward direction.

7. The detector element according to claim 1, wherein two active layers, between which an electrical terminal contact is arranged, are formed as photodiodes with the same forward direction, and a tunnel diode is arranged between the two active layers.

8. The detector element according to claim 1, wherein thicknesses of the active layers increase or decrease in a growth direction of the epitaxial semiconductor layer sequence.

9. The detector element according to claim 1, wherein the epitaxial semiconductor layer sequence has a thickness such that an optical path length of electromagnetic radiation with a wavelength L1 between the first main surface and the second main surface of the epitaxial semiconductor layer sequence corresponds to an integer multiple of the wavelength L1.

10. The detector element according to claim 1, wherein the semiconductor layer sequence comprises at least three active layers, and
an average distance A2 between two neighboring active layers, between which no electrical terminal contact is arranged, is A2=L1*m/(2*n), where n is an average refractive index of the semiconductor layer sequence and m is a positive integer.

11. A lidar module, comprising:
an epitaxial semiconductor layer sequence with at least two active layers that are configured for absorbing electromagnetic radiation having a wavelength L1, wherein the epitaxial semiconductor layer sequence comprises a first main surface and a second main surface opposite to the first main surface, each of which is configured for coupling in and for coupling out electromagnetic radiation,
at least three electrical terminal contacts that are configured for electrically contacting the active layers, wherein one electrical terminal contact is arranged between two active layers,
a laser light source configured for generating coherent electromagnetic radiation at the wavelength L1, wherein
electromagnetic radiation generated during operation by the laser light source is coupled into the epitaxial semiconductor layer sequence via the first main surface and is coupled out via the second main surface.

12. The lidar module according to claim 1, wherein the laser light source comprises a surface-emitting semiconductor layer sequence, wherein the surface-emitting semiconductor layer sequence and the epitaxial semiconductor layer sequence of the detector element form a monolithic semiconductor layer stack.

13. The lidar module according to claim 11, wherein a plurality of detector elements are arranged on a transparent carrier and form a two-dimensional detector array.

14. A method for operating a lidar module comprising:
transmitting a transmission signal, wherein the transmission signal comprises a frequency-modulated electromagnetic wave with a wavelength L1 generated by a laser light source, which passes through a detector element and is subsequently at least partially reflected by an external object, wherein the detector element comprises an epitaxial semiconductor layer sequence with at least two active layers that are configured for absorbing the electromagnetic radiation with the wavelength L1, and the epitaxial semiconductor layer sequence comprises a first main surface and a second main surface opposite to the first main surface, wherein the transmission signal is coupled into the detector element via the first main surface,
receiving a receiving signal that comprises the transmission signal that is at least partially reflected by an external object, wherein the receiving signal is coupled into the detector element via the second main surface and is superimposed there with the counter-propagating transmission signal, whereby a standing electromagnetic wave is formed,
differentially measuring a beating frequency of the standing electromagnetic wave by measuring the photocurrents of the active layers with a differential amplifier, and
determining a distance to the external object from the beating frequency.

15. The method for operating a lidar module according to claim 14, wherein a systematic difference in intensity of the electromagnetic radiation in the active layers is compensated by a dynamic circuit.
